(19) United States
(12) Patent Application Publication
(10) Pub. No.: US 2001/0046122 A1
(43) Pub. Date: Nov. 29, 2001

(54) Computer shroud

(76) Inventor: Chance Nygard, Anchorage, AK (US)

Correspondence Address: Michael Tavella, 2051 Brigadier Dr, Anchorage, AK, 99507, US

(21) Appl. No.: 09/822,902

(22) Filed: Mar. 29, 2001

Related U.S. Application Data
(60) Provisional application No. 60/193,824, filed on Mar. 31, 2000.

(51) Int. Cl. H05K 5/00

(52) U.S. Cl. 361/726; 361/724

(57) ABSTRACT

A housing or shroud for computers. In the preferred embodiment, the shroud is designed to fit over tower style CPUs. The shroud fits over the face of the CPU and has a hinged door that can be locked in a closed position. In this position, the shroud protects the face of the CPU from dirt, dust and liquids. Moreover, the shroud is made of high strength plastic components. Thus, the CPU is protected by a strong housing. Finally, the shroud can be used with security cables that are secured to the CPU. Once secured, the shroud cannot be removed and a thief is prevented from gaining access to the computer or any disks that may be installed in the CPU.

### CROSS REFERENCE TO RELATED APPLICATIONS

This application claims priority based on U.S. Provisional Application No. 60/193,824, filed Mar. 31, 2000

### STATEMENT REGARDING FEDERALLY SPONSORED RESEARCH AND DEVELOPMENT

Not Applicable

### BACKGROUND OF THE INVENTION

1. Field of the Invention

This invention relates to computer shields and particularly to computer shields that have front access doors.

2. Description of the Prior Art

Modern computers have a main housing that contains the CPU, hard drive, CD ROM drawer and floppy drives. The housing is often built in a “tower” design in which the housing is a vertical mass that typically sits on the floor of a home or office. Many computer desks and carts have been designed to hold these towers. Because towers are located under desks and tables, they are exposed to dirt, dust, and children more than ever before. Moreover, liquids such as drinks can be easily spilled on an exposed tower CPU. Not only is the CPU exposed, in many cases the CPU tower has a CD-ROM drive and possibly a floppy disk drive as well. These devices rely on a clean environment and even small amounts of dirt or liquids can severely damage them.

Computers are also subject to theft and security problems. Access to CPUs and computers is becoming a serious problem. Information stored within the computer or on disks can be accessed by someone with access to the CPU. Moreover, access to the CPU controls allows hackers or others to “break into” computer systems to use the computers for all types of illegal activities.

### BRIEF DESCRIPTION OF THE INVENTION

To prevent security problems and damage to the computers, I have designed a housing or shroud for computers. The shroud fits over the face of the CPU and has a hinged door that can be locked in a closed position. In this position, the shroud protects the face of the CPU from dirt, dust and liquids. Moreover, the shroud is made of high strength plastic components. Thus, the CPU is protected by a strong housing. Finally, the shroud can be used with security cables that are secured to the CPU. Once secured, the shroud cannot be removed and a thief is prevented from gaining access to the computer or any disks that may be installed in the CPU.

### BRIEF DESCRIPTION OF THE DRAWINGS

FIG. 1 is a perspective view of the preferred embodiment of the invention showing the access door closed.

FIG. 2 is a perspective view of a second embodiment of the invention showing the access door closed.

FIG. 3 is a perspective view of the second embodiment of the invention showing the access door open.

FIG. 4 is a top plan view of the shroud installed on a computer case showing the strap loosely wrapped around the computer case.

FIG. 5 is a top plan view of the shroud installed on a computer case showing the cables and adhesive pads in place.

FIG. 6 is a top plan view of the shroud without the computer in place.

FIG. 7 is a side view of the shroud without the computer in place.

### DETAILED DESCRIPTION OF THE INVENTION

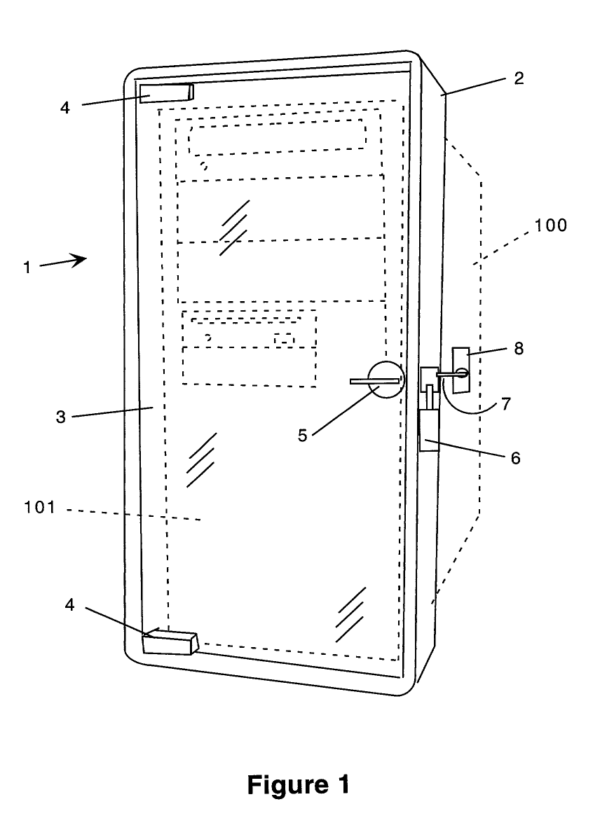

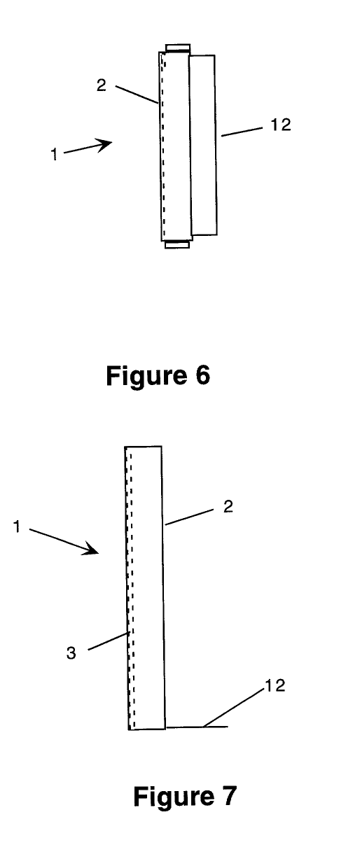

Referring now to FIG. 1, the computer shroud 1 is designed to protect the face of modem, personal computers. The shroud is a rectangular frame 2 that is sized to fit around the perimeter of a tower computer 100. The frame 2 has an open back so that the tower can fit within the shroud as shown. The shroud 1 is shallow in depth. It is designed to cover only the face 101 of the computer and the surrounding edges of the case. In an optional embodiment, an extension foot 12 (see FIGS. 6 and 7) is formed on the bottom of the frame 2. This foot 12 is designed to fit under the front of the tower and serves to hold the shroud in place. This foot is not preferred, however, because it provides minimal security for the computer. The foot 12 is not required in the other embodiments discussed herein. However, there is no reason that it cannot be added to these embodiments, if desired.

The front of the frame 2 is open as well. To cover the face of the computer, a clear door 3 is secured to the front of the frame 2. A pair of hinges 4 allows the door to be opened to access the computer controls and interfaces. The clear door 3 allows the user to see the operation of the computer.

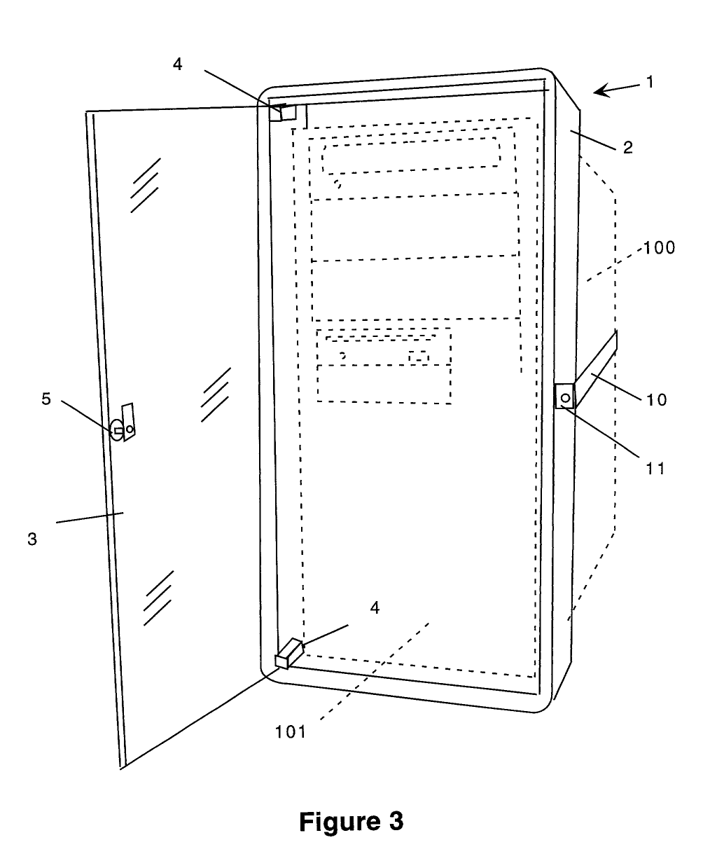

A locking latch 5 is attached to the door as shown. The inner part of the catch is attached to the frame 2. The door is held closed by the latch 5 when it the computer is in use and can be locked when the computer is shut down. When access is needed to the computer, the latch 5 is opened. The door can then be opened to operate the computer as needed See, FIG. 3. Of course, any similar type of catch may be used to operate the door, including a magnetic style catch for less secure uses. Moreover, although the hinges are shown on the left side of the frame 2 and the latch 5 is shown on the right, these components can be reversed or positioned in any convenient location.

FIG. 1 shows the preferred embodiment. This embodiment is the most secure. It has a lock 6 to prevent unauthorized access to the computer. It also has a pair of cables 7 (note there is only one cable shown in FIG. 1; the additional cable is located on the other side of the shroud as shown in FIG. 5). Two adhesive pads 8 are attached to the sides of the CPU as shown. These pads use a type of adhesive that bonds tightly, making removal difficult. Thus, access to the computer is prevented because there is no way to remove the shroud without damaging the computer itself.

The use of the shroud and door also prevents accidental damage to the computer. The shroud prevents dust, dirt, and spilled items from getting onto the front of the computer, including the CD-ROM drive and the floppy disk drive.

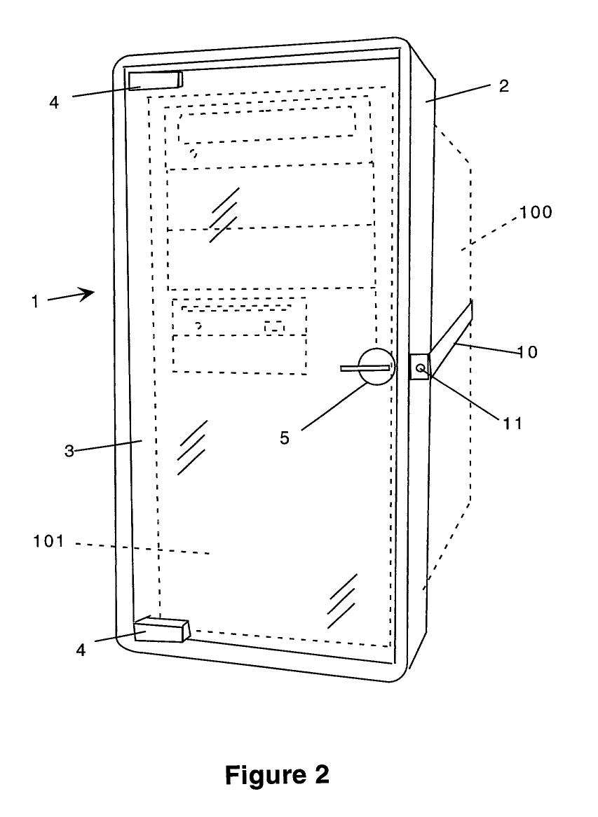

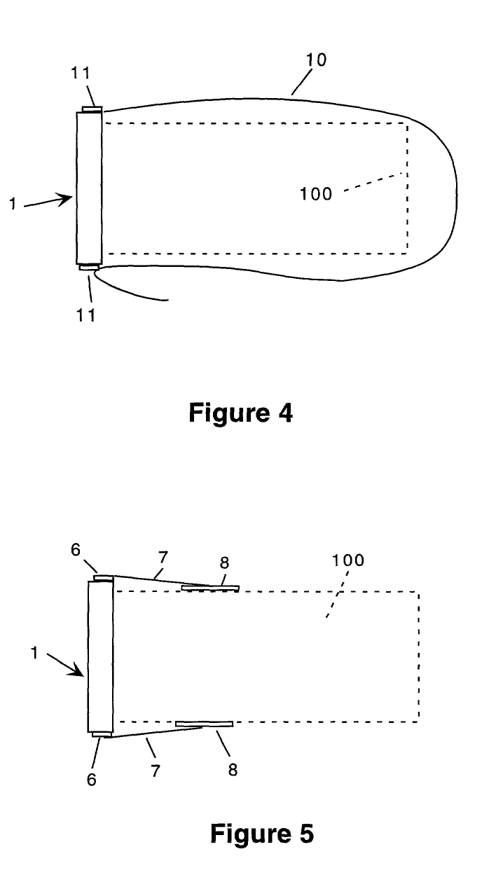

Referring now to FIG. 2, a second embodiment of the invention is shown. It has a similar structure to the first embodiment. Here, however, the security cables 7 and adhesive pads 8 are replaced with a VELCRO strap 10, made of a hook and loop type fastener. This embodiment is preferred for low security areas such as homes. The strap prevents small children from pulling the shroud from the computer and prevents their access to the machine. As shown in FIG. 4, the strap 10 is fastened to one side of the frame 2 using a connector 11. A second connector 11 is placed on the opposite side of the frame 2 as shown. This connector is designed to allow the strap to pass through the connector as fold back on itself. In this way, the strap can be wrapped loosely around the case (as shown in FIG. 4), passed through connector 11, and then pulled back until the strap is tight. The VELCRO allows the strap to be folded over to secure it in the tightened position.

FIG. 3 shows the second embodiment with the door 3 open. As shown, the door swings open on the hinges 4. The open door allows full access to the computer controls. Note that in the case of the first embodiment, the door operates in the same way. However, here, the lock must first be removed.

The shroud 1 can be made to any size and shape to cover the vast majority of tower-type computers in use today. For example, one model size has sidewalls that are 17.25 inches high and 2 inches wide. A top wall that is 7 inches wide and 2 inches deep, a bottom wall that is 7 inches wide and 2 inches deep. Note that if the bottom wall has the foot 12 formed in it, the bottom wall is 7 inches wide by 4 inches deep. As mentioned above, these dimensions are adjustable to fit any type of computer made.

In both embodiments, the shroud 1 is made of plastic. The shroud body can be made of clear or colored plastic. The door is made of clear plastic, LEXAN, or similar material.

The present disclosure should not be construed in any limited sense other than that limited by the scope of the claims having regard to the teachings herein and the prior art being apparent with the preferred form of the invention disclosed herein and which reveals details of structure of a preferred form necessary for a better understanding of the invention and may be subject to change by skilled persons within the scope of the invention without departing from the concept thereof.

I claim:

1. A shroud for a computer case comprising:
a) a frame, having an open back and an open front;
b) a door, hingably attached to said open front of said frame;
c) a means for securing said door in a closed position; and
d) a means for securing said frame around a computer case.

2. The shroud of claim 1 wherein said means for securing said door in a closed position comprises a latch.

3. The shroud of claim 2 where the latch further comprises a means for locking said latch.

4. The shroud of claim 1 wherein the means for securing said frame around a computer case comprise a foot attached to said frame and extending outwardly therefrom such that when said shroud is placed around said computer case, said foot is placed underneath said computer case.

5. The shroud of claim 1 wherein the means for securing said frame around a computer case comprises:
a) a strap;
b) a means for fixedly securing said strap to said frame at a first side;
c) a means for removably attaching the strap to a second side of said frame;
d) whereby said strap is passed around the computer case after said frame is positioned around the computer case and secured to the means for removably attaching the strap to secure the frame to the computer case.

6. The shroud of claim 5 wherein the strap is made of a hook and loop type fastener.

7. The shroud of claim 1 wherein the means for securing said frame around a computer case comprise:
a) a first cable having a proximate end and a distal end, said proximate end of said first cable being fixedly attached to a first side of said frame;
b) a second cable having a proximate end and a distal end, said proximate end of said second cable being fixedly attached to a second side of said frame;
c) a first adhesive pad, fixedly attached to the distal end of said first cable;
d) a second adhesive pad, fixedly attached to the distal end of said second cable;
e) whereby said first and second adhesive pads being fixedly attached to said computer case after said frame is positioned around said computer case.

8. A shroud for a computer case comprising:
a) a generally rectangular frame, having an open back and an open front;
b) a door, hingably attached to said open front of said frame;
c) a latch, operably attached to said door for holding said door in a closed position; and
d) a means for securing said frame around a computer case.

9. The shroud of claim 8 where the latch further comprises a means for locking said latch.

10. The shroud of claim 8 wherein the means for securing said frame around a computer case comprise a foot attached to said frame and extending outwardly therefrom such that when said shroud is placed around said computer case, said foot is placed underneath said computer case.

11. The shroud of claim 8 wherein the means for securing said frame around a computer case comprises:
a) a strap;
b) a means for fixedly securing said strap to said frame at a first side;
c) a means for removably attaching the strap to a second side of said frame;
d) whereby said strap is passed around the computer case after said frame is positioned around the computer case and secured to the means for removably attaching the strap to secure the frame to the computer case.

12. The shroud of claim 11 wherein the strap is made of a hook and loop type fastener.

13. The shroud of claim 8 wherein the means for securing said frame around a computer case comprise:
a) a first cable having a proximate end and a distal end, said proximate end of said first cable being fixedly attached to a first side of said frame;
b) a second cable having a proximate end and a distal end, said proximate end of said second cable being fixedly attached to a second side of said frame;
c) a first adhesive pad, fixedly attached to the distal end of said first cable;
d) a second adhesive pad, fixedly attached to the distal end of said second cable;
e) whereby said first and second adhesive pads being fixedly attached to said computer case after said frame is positioned around said computer case.
